(19) United States
(12) Patent Application Publication
(10) Pub. No.: US 2022/0005689 A1
(43) Pub. Date: Jan. 6, 2022

(54) SEMICONDUCTOR PROCESS

(71) Applicant: UNITED MICROELECTRONICS CORP., Hsinchu (TW)

(72) Inventor: Suz-Ping LIANG, Taoyuan City (TW)

(21) Appl. No.: 16/990,049

(22) Filed: Aug. 11, 2020

(30) Foreign Application Priority Data
Jul. 1, 2020 (CN) 202010626386.2

(51) Int. Cl. H01L 21/02; H01L 21/321; H01L 21/306

(52) U.S. Cl. CPC H01L 21/02087; H01L 21/30625; H01L 21/3212

(57) ABSTRACT

A semiconductor process includes a first force supplying step and a second force supplying step. The first force supplying step is supplying a first uniform centrifugal force to a cleaning liquid provided on a wafer surface of a wafer. The second force supplying step is supplying a second uniform centrifugal force to the cleaning liquid provided on the wafer surface. The second force supplying step is after the first force supplying step. The second uniform centrifugal force is bigger than the first uniform centrifugal force.

This application claims the benefit of People's Republic of China application Serial No. 202010626386.2, filed Jul. 1, 2020, the subject matter of which is incorporated herein by reference.

### BACKGROUND

### Technical Field

The disclosure relates to a semiconductor process, and particularly relates to an edge bevel cleaning process.

### Description of the Related Art

In a semiconductor process, an electro chemical plating (ECP) process may be used to form a metal layer of copper. Then, an edge bevel removal (EBR) process may be performed to clean the copper remainder on a wafer edge with using a chemical agent of an aqueous solution of hydrogen peroxide (H₂O₂) and sulfuric acid (H₂SO₄), for example. It can prevent a metal surface from damages that would occur due to the copper remainder peeling from the wafer edge during a follow-up chemical mechanical polishing, affecting subsequent manufacturing processes.

### SUMMARY

The present disclosure relates to a semiconductor process.

According to a concept of the present disclosure, a semiconductor process is provided. The semiconductor process comprises a first force supplying step and a second force supplying step. The first force supplying step is supplying a first uniform centrifugal force to a cleaning liquid provided on a wafer surface of a wafer. The second force supplying step is supplying a second uniform centrifugal force to the cleaning liquid provided on the wafer surface. The second force supplying step is after the first force supplying step. The second uniform centrifugal force is bigger than the first uniform centrifugal force.

According to another concept of the present disclosure, a semiconductor process is provided, comprising the following steps. A first rotating step and a cleaning liquid providing step are performed during a first period of time. The first rotating step is rotating a wafer at a first uniform rotation speed. The cleaning liquid providing step is providing a cleaning liquid onto a wafer surface of the wafer. Then, a second rotating step and the cleaning liquid providing step are performed during a second period of time. The second rotating step is rotating the wafer at a second uniform rotation speed faster than the first uniform rotation speed.

### BRIEF DESCRIPTION OF THE DRAWINGS

FIG. 1 is a diagram illustrating a semiconductor process according to an embodiment.

FIG. 2 illustrates a timing diagram of the semiconductor process according to an embodiment.

FIG. 3 is a schematic diagram illustrating the wafers after being cleaned in a comparative example and an embodiment.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

Embodiments are provided hereinafter with reference to the accompanying drawings for describing the related procedures and configurations. It is noted that not all embodiments of the invention are shown. Also, it is noted that there may be other embodiments of the present disclosure which are not specifically illustrated. Modifications and variations can be made without departing from the spirit of the disclosure to meet the requirements of the practical applications. It is also important to point out that the illustrations may not be necessarily be drawn to scale. Thus, the specification and the drawings are to be regard as an illustrative sense rather than a restrictive sense. The identical and/or similar elements of the embodiments are designated with the same and/or similar reference numerals.

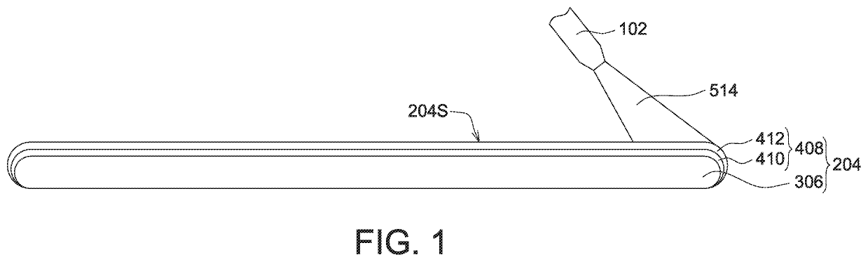

FIG. 1 is referred to, which is a diagram illustrating a semiconductor process. A nozzle 102 may be positioned over a wafer 204 and adjacent to an edge of the wafer 204. The nozzle 102 is used for providing a cleaning liquid 514 onto a wafer surface 204S (which may include a wafer sidewall surface and an upper wafer surface adjacent to the wafer sidewall surface) of the wafer 204. In an embodiment, the nozzle 102 is arranged with a position to be capable of ejecting the cleaning liquid 514 from an exit hole along a direction towards the wafer sidewall surface of the wafer 204 as shown in FIG. 1.

The wafer 204 may comprise a semiconductor substrate 306 and a metal containing film 408 on the semiconductor substrate 306. For example, the semiconductor substrate 306 comprises silicon (such as a silicon wafer) or other suitable semiconductor materials. The metal containing film 408 may comprise a metal, an oxide of the metal, a nitride of the metal, etc. For example, the metal containing film 408 may comprise a metal layer 410. For example, the metal layer 410 may be formed by a depositing method, a coating method, or other methods. The metal containing film 408 may also comprise a metal oxide layer 412 on the metal layer 410. The metal oxide layer 412 may be a layer formed by an oxidation of a surface of the metal layer 410, such as a native oxide layer, or by a depositing method, a coating method, or other methods. In an embodiment, the metal layer 410 comprises copper, the metal oxide layer 412 comprises copper oxide, and the cleaning liquid 514 for cleaning copper/copper oxide may comprise an aqueous solution of hydrogen peroxide (H₂O₂) and sulfuric acid (H₂SO₄) (i.e. a mixture solution of hydrogen peroxide, sulfuric acid and water). However, the present disclosure is not limited thereto. In another embodiment, the metal of the metal containing film 408 may comprise cobalt or other kinds of metal, and the cleaning liquid 514 (or etchant liquid) for cleaning (or etching) the metal containing film 408 may select proper solutions correspondingly. In FIG. 1, it is shown that the wafer surface 204S onto which the cleaning liquid 514 is provided comprises a surface of the metal oxide layer 412. However, it could be realized that, in some conditions, for example, as there is no metal oxide layer 412 formed on the metal layer 410, or as the metal layer 410 under the metal oxide layer 412 is exposed after the metal oxide layer 412 is removed through a cleaning step (such as a removing step), the wafer surface 204S onto which the cleaning liquid 514 is provided comprises a surface of the metal layer 410.

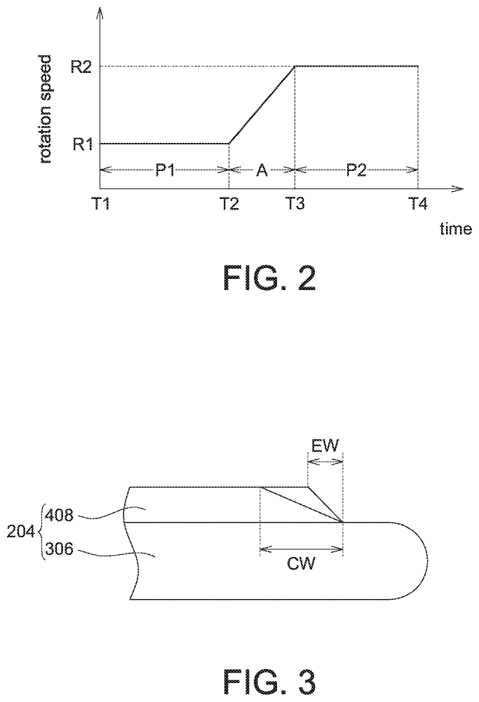

FIG. 2 illustrates a timing diagram of the semiconductor process. FIG. 1 and FIG. 2 are referred to. In embodiments, the semiconductor process is a process for removing a thin film on a wafer edge and bevel. The semiconductor process comprises performing a cleaning liquid providing step and a first force supplying step, for continuously providing the cleaning liquid 514 onto the wafer 204 and making the cleaning liquid 514 on the wafer 204 leaving from the wafer 204 at a uniform slower flow speed, during a first period of time P1 from a time point T1 to a time point T2. The cleaning liquid providing step is providing the cleaning liquid 514 onto the wafer 204. In an embodiment, the first force supplying step is supplying a first uniform centrifugal force F1 to the cleaning liquid 514 on the wafer 204 so as to make the cleaning liquid 514 leave from the wafer 204 at the slower flow speed (such as a radial flow speed). In an embodiment, the first uniform centrifugal force F1 may be generated by a first rotating step being rotating the wafer 204 at a first rotation speed R1. The first rotation speed R1 may be a uniform rotation speed (i.e. a first uniform rotation speed). In an embodiment, the first rotation speed R1 is 100-400 rpm. The cleaning liquid 514 with the slower flow speed can stay on the wafer 204 for a longer period of time. The metal containing film 408 can have a bigger taper width by being cleaned with the cleaning liquid 514 having the slower flow speed. In an embodiment, the cleaning liquid 514 applied by a lower centrifugal force will have the slower flow speed, and therefore can stay on the wafer 204 for a longer period of time, so as to efficiently remove the rigid metal oxide layer 412 which is on the metal layer 410, and further to expose the metal layer 410, or efficiently dissolve the metal layer 410 (e.g. copper).

Then, during a second period of time P2, the cleaning liquid providing step and a second force supplying step are performed for continuously providing the cleaning liquid 514 onto the wafer 204 and making the cleaning liquid 514 on the wafer 204 leaving from the wafer 204 at a uniform faster flow speed. In an embodiment, the second force supplying step is supplying a second uniform centrifugal force F2, bigger than the first uniform centrifugal force F1, to the cleaning liquid 514 on the wafer 204 so as to make the cleaning liquid 514 leave from the wafer 204 at the faster flow speed (such as a radial flow speed) and avoid flowing the cleaning liquid 514 back to an interior of the wafer 204 affecting the region not expected to be cleaned/removed by the cleaning liquid 514. In an embodiment, the second uniform centrifugal force F2 may be generated by a second rotating step being rotating the wafer 204 at a second rotation speed R2. The second rotation speed R2 may be a uniform rotation speed (i.e. a second uniform rotation speed). The second rotation speed R2 is faster than the first rotation speed R1 of the first rotating step performed during the first period of time P1. In an embodiment, a ratio (i.e. R2/R1) of the second rotation speed R2 to the first rotation speed R1 is bigger than 1, and is smaller than or identical to 4. In other words, 1<R2/R1≤4. The cleaning liquid 514 with the faster flow speed that applies after the slower flow speed can stay on the wafer 204 for a shorter period of time. In an embodiment, the metal containing film 408 can have a steeper taper or a narrower taper width (such as a taper width EW as shown in FIG. 3) by being cleaned with the cleaning liquid 514 having the faster flow speed. After the second period of time P2, a chemical mechanical polishing process may be performed to the wafer 204. Since the metal containing film 408 has a narrower taper width, the process problems of peeling particles of metal (such as copper particles) and surface scraping defects of a material layer resulted from the particles that would happen during the chemical mechanical polishing process can be improved.

In embodiments, the semiconductor process may comprise an acceleration period of time A, between the first period of time P1 and the second period of time P2. The acceleration period of time A may be a period of time from the time point T2 to a time point T3. The second period of time P2 may be a period of time from the time point T3 to a time point T4. In an embodiment, during the acceleration period of time A, the cleaning liquid providing step and a force enhancing step may be performed. The force enhancing step is enhancing a centrifugal force supplied to the cleaning liquid 514 on the wafer 204 from the first uniform centrifugal force F1 to the second uniform centrifugal force F2, for example, from the first uniform centrifugal force F1 to the second uniform centrifugal force F2, linearly. In an embodiment, the enhancing of the centrifugal force is generated by an accelerating step being constantly accelerating a rotation speed of the wafer 204 from the first rotation speed R1 to the second rotation speed R2.

In an embodiment, the cleaning liquid 514 may be continuously and constantly supplied by the nozzle 102 at a uniform and un-varied flow rate during the first period of time P1, the second period of time P2 and the acceleration period of time A. In an embodiment, before the first period of time P1, the rotation speed of the wafer 204 may be constantly accelerated from a stationary state to the first rotation speed R1. The cleaning liquid 514 is supplied onto the wafer 204 only after the rotation speed achieves the first rotation speed R1. An initial time point starting supplying the cleaning liquid 514 may correspond to the time point T1 shown in FIG. 2. In an embodiment, the cleaning liquid 514 may be supplied onto the wafer 514 during the first period of time P1 and the second period of time P2, and not supplied during the acceleration period of time A. The first period of time P1 and the second period of time P2 may be 1 second to 10 minutes individually. In an embodiment, for example, the first period of time P1 may be 2 seconds to 1 minute, and the second period of time P2 may be 2 seconds to 5 minutes.

FIG. 3 is a schematic diagram illustrating the wafers after being cleaned in a comparative example and an embodiment. FIG. 2 and FIG. 3 are referred to. In the comparative example, during the period of time from the time point T1 to the time point T4, the wafer 204 is rotated at a single rotation speed RC bigger than the first rotation speed R1 and smaller than the second rotation speed R2, and a taper width of the wafer 204 resulted from being cleaned by the such method is indicated as CW. In the embodiment, the wafer 204 is rotated at the uniform first rotation speed R1, and then rotated at the uniform second rotation speed R2 faster than the first rotation speed R1, and a taper width of the wafer 204 resulted from being cleaned by the such method is indicated as EW. The taper width EW of the embodiment is narrower than the taper width CW of the comparative example. The taper width EW in some embodiments is a reduced taper width by about 10% compared with the taper width CW in the comparative example. Accordingly, by the semiconductor process in embodiments, the metal containing film 408 having the narrower taper width EW is formed. It can improve the process problems of peeling particles of metal (such as copper particles) and surface scraping defects of a material layer resulted from the particles that would happen during a follow-up chemical mechanical polishing process. Otherwise, it can increase an effective die area on a wafer surface.

Accordingly, in embodiments, the cleaning liquid is continuously provided onto the wafer, and the cleaning liquid on the wafer is made to leave from the wafer at the uniform slower flow speed, and then leave form the wafer at the uniform faster flow speed. By the process for removing a metal layer of edge using such method, the metal containing film (such as a copper film) having a narrower taper width can be formed. It can improve the process problems of peeling particles of metal (such as copper particles) and surface scraping defects of a material layer resulted from the particles that would happen during a follow-up chemical mechanical polishing process. Otherwise, it can increase an effective die area on a wafer surface.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

1. A semiconductor process, comprising:
ejecting a cleaning liquid from a nozzle aiming at a wafer edge of a wafer and at the same time making the cleaning liquid on the wafer leaving from the wafer at a uniform slower flow speed by a first force supplying step being supplying a first uniform centrifugal force to the cleaning liquid provided on the wafer; and
then ejecting the cleaning liquid from the nozzle aiming at the wafer edge of the wafer and at the same time making the cleaning liquid on the wafer leaving from the wafer at a uniform faster flow speed by a second force supplying step being supplying a second uniform centrifugal force to the cleaning liquid on the wafer, wherein the second force supplying step is after the first force supplying step, the second uniform centrifugal force is bigger than the first uniform centrifugal force.

2. The semiconductor process according to claim 1, further comprising a force enhancing step being enhancing a force supplying to the cleaning liquid on the wafer from the first uniform centrifugal force to the second uniform centrifugal force.

3. The semiconductor process according to claim 2, wherein the centrifugal force supplied to the cleaning liquid on the wafer surface is enhanced linearly from the first uniform centrifugal force to the second uniform centrifugal force.

4. The semiconductor process according to claim 1, wherein the first force supplying step and the second force supplying step are performed by rotating the wafer.

5. The semiconductor process according to claim 1, wherein the first force supplying step is performed by rotating the wafer at a first rotation speed, the second force supplying step is performed by rotating the wafer at a second rotation speed faster than the first rotation speed.

6. The semiconductor process according to claim 5, wherein a ratio of the second rotation speed to the first rotation speed is bigger than 1, and is smaller than or identical to 4.

7. The semiconductor process according to claim 5, wherein the first rotation speed is 100-400 rpm.

8. The semiconductor process according to claim 1, wherein the nozzle is positioned adjacent to the wafer edge.

9. The semiconductor process according to claim 1, further comprising performing a chemical mechanical polishing process to the wafer after the second force supplying step.

10. (canceled)

11. The semiconductor process according to claim 1, wherein the wafer comprises a semiconductor substrate and a metal containing film on the semiconductor substrate.

12. A semiconductor process, comprising:
ejecting a cleaning liquid from a nozzle aiming at a wafer edge of a wafer and at the same time making the cleaning liquid on the wafer leaving from the wafer at a uniform slower flow speed by performing a first rotating step during a first period of time, wherein the first rotating step is rotating the wafer at a first uniform rotation speed; and
then ejecting the cleaning liquid from the nozzle aiming at the wafer edge of the wafer and at the same time making the cleaning liquid on the wafer leaving from the wafer at a uniform faster flow speed by performing a second rotating step during a second period of time, wherein the second rotating step is rotating the wafer at a second uniform rotation speed faster than the first uniform rotation speed.

13. The semiconductor process according to claim 12, further comprising an accelerating step being accelerating a rotation speed of the wafer from the first uniform rotation speed to the second uniform rotation speed.

14. The semiconductor process according to claim 12, wherein a ratio of the second uniform rotation speed to the first uniform rotation speed is bigger than 1, and is smaller than or identical to 4.

15. The semiconductor process according to claim 12, wherein the first uniform rotation speed is 100-400 rpm.

16. The semiconductor process according to claim 12, wherein the nozzle is positioned adjacent to the wafer edge.

17. The semiconductor process according to claim 12, further comprising performing a chemical mechanical polishing process to the wafer after the second rotating step.

18. (canceled)

19. The semiconductor process according to claim 12, wherein the wafer comprises a semiconductor substrate and a metal containing film on the semiconductor substrate.

20. (canceled)
